(19) United States
(12) Patent Application Publication
(10) Pub. No.: US 2026/0011702 A1
(43) Pub. Date: Jan. 8, 2026

(54) POWER AND SIGNAL DISTRIBUTION IN STACKED SEMICONDUCTOR SYSTEMS

(71) Applicant: Micron Technology, Inc., Boise, ID (US)

(72) Inventor: Gregory A. King, Boise, ID (US)

(21) Appl. No.: 19/258,736

(22) Filed: Jul. 2, 2025

Related U.S. Application Data
(60) Provisional application No. 63/668,712, filed on Jul. 8, 2024.

(51) Int. Cl. H01L 25/16; G11C 5/14; H01L 21/768; H01L 23/00; H01L 23/48; H01L 25/00

(52) U.S. Cl. CPC H01L 25/16; H01L 21/76898; H01L 23/481; H01L 24/08; H01L 24/80; H01L 25/50; G11C 5/14; H01L 2224/08145; H01L 2224/80895; H01L 2224/80896

(57) ABSTRACT

Methods, systems, and devices for power and signal distribution in stacked semiconductor systems are described. A semiconductor system may include a distribution component configured to communicate power, signals, or both with a logic component and memory component(s) of the semiconductor system. The distribution component may include power delivery circuitry to provide separate power to the memory component(s) and the logic component, data serialization/deserialization circuitry to communicate data signals with the logic component, or both. The distribution component may convey power, data signals, or both to the logic component using conductive vias that pass through the memory components and bypass interface circuitry of the memory component(s). The distribution component may include clock circuitry that receives, generates, or both, one or more clock signals and provides the one or more clock signals for I/O functionality of the distribution component, the logic component, the interface circuitry, or any combination thereof.

### CROSS REFERENCE

The present application for patent claims priority to U.S. Patent Application No. 63/668,712 by King, entitled “POWER AND SIGNAL DISTRIBUTION IN STACKED SEMICONDUCTOR SYSTEMS,” filed Jul. 8, 2024, which is assigned to the assignee hereof, and which is expressly incorporated by reference in its entirety herein.

### TECHNICAL FIELD

The following relates to one or more semiconductor systems, including power and signal distribution in stacked semiconductor systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports power and signal distribution in stacked semiconductor systems in accordance with examples as disclosed herein.

FIG. 2 shows an example of a system that supports power and signal distribution in stacked semiconductor systems in accordance with examples as disclosed herein.

FIG. 3 shows an example of a system that supports power and signal distribution in stacked semiconductor systems in accordance with examples as disclosed herein.

FIG. 4 shows a block diagram of a system that supports power and signal distribution in stacked semiconductor systems in accordance with examples as disclosed herein.

FIGS. 5 through 7 show flowcharts illustrating methods that support power and signal distribution in stacked semiconductor systems in accordance with examples as disclosed herein.

### DETAILED DESCRIPTION

Some semiconductor systems (e.g., memory systems, processor systems) may include a stack of semiconductor components (e.g., dies), which may include one or more memory dies or one or more stacks of memory dies that are stacked with a logic die operable to access a set of memory arrays distributed across the one or more memory dies. Such a stacked architecture may be implemented as part of a high bandwidth memory (HBM) system or a closely-coupled dynamic random access memory (e.g., a 3D stacked memory) system, among other examples. Such stacked architecture may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface circuitry (e.g., memory interface blocks, interface blocks), logic circuitry (e.g., logic blocks), controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

In some semiconductor systems, a stack of memory components (e.g., memory dies, memory chips, a memory stack, of an HBM or 3D stacked memory system) may be bonded on top of a logic component (e.g., a logic die, a logic device, a logic compute die, a processing chip) in a heterogeneous stack (e.g., 3D stack including different die types). However, placing a relatively high-power logic component at or near the bottom of a heterogeneous stack may result in thermal challenges, because a thermal impedance of the memory components may trap heat generated by the logic component. For example, heat generated by a logic component may be rejected (e.g., transferred) through memory components to a heat sink (e.g., a cold plate) at another end of the stack, resulting in relatively high temperature gradient and peak temperature (e.g., at or near the logic component). In some cases, thermal effects for heterogeneous stacks may be mitigated by placing a component with a relatively high thermal output (e.g., a relatively substantial heat source), such as a logic component, as an upper device (e.g., opposite a system substrate or installation surface) for closer integration with a heat sink. In some cases, placing a logic component over a stack of memory components (e.g., memory dies) may be referred to as a Logic-on-Top (LoT) configuration. However, LoT configurations may be associated with challenges for providing power to different semiconductor components of a stack (e.g., providing power in accordance with different configurations to a logic component and one or more memory components), or for supporting serialized communications with the logic component (e.g., through or across a stack of memory components), or both.

In accordance with examples as disclosed herein, a semiconductor system (e.g., a stacked semiconductor system, a stack of semiconductor dies, in a LOT configuration) may include a distribution component (e.g., a distribution die, an interposer, a logic input/output (I/O)/power distribution network (PDN) die) coupled with one or more memory components (e.g., memory dies, of a memory stack) and a logic component, where the distribution component may communicate power, signals (e.g., data signals), or both with other semiconductor components of the stack. The distribution component may include power delivery circuitry (e.g., power distribution circuitry) configured to provide separate power (e.g., in accordance with different voltages, different regulation schemes, different power conductors) to the one or more memory components and the logic component. Additionally, or alternatively, the distribution component may also include circuitry for data serialization and deserialization (e.g., data serialization/deserialization circuitry, referred to herein as a SERDES), which may communicate data signals with the logic component. In some cases, the distribution component may convey power, data signals, or both to or with the logic component using conductive vias (e.g., through-silicon vias (TSVs)) that pass through the memory components and bypass interface circuitry of the memory component(s). Additionally, or alternatively, the distribution component may include clock circuitry configured to provide clock signals for I/O functionality of the distribution component, for the logic component, for the interface circuitry, or any combination thereof. In some cases, the clock circuitry may receive one or more clock signals from another component (e.g., a substrate component, a host system, an external clock generator), or may generate one or more clock signals, or both.

In addition to applicability in memory systems as described herein, techniques for power and signal distribution in stacked semiconductor systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by distributing power delivery and serialization/deserialization circuitry among a stack of semiconductor components, reducing an allocation of other components (e.g., of a logic die, of memory dies) to such features and improving design flexibility for interfacing with other components (e.g., a package substrate, an assembly substrate, a compute system). Such techniques may support a relatively high power consumption for operations of a logic die and memory dies, while providing the logic die with a more-direct heat rejection path (e.g., opposite the stack of semiconductor components), which may support improved temperature uniformity, higher power density, higher processing density, improved processing speed, and overall improvements to user experience, among other benefits.

Features of the disclosure are illustrated and described in the context of systems (e.g., semiconductor systems) and architectures. Features of the disclosure are further illustrated and described in the context of flowcharts (e.g., illustrating one or more methods of operating or forming a semiconductor system).

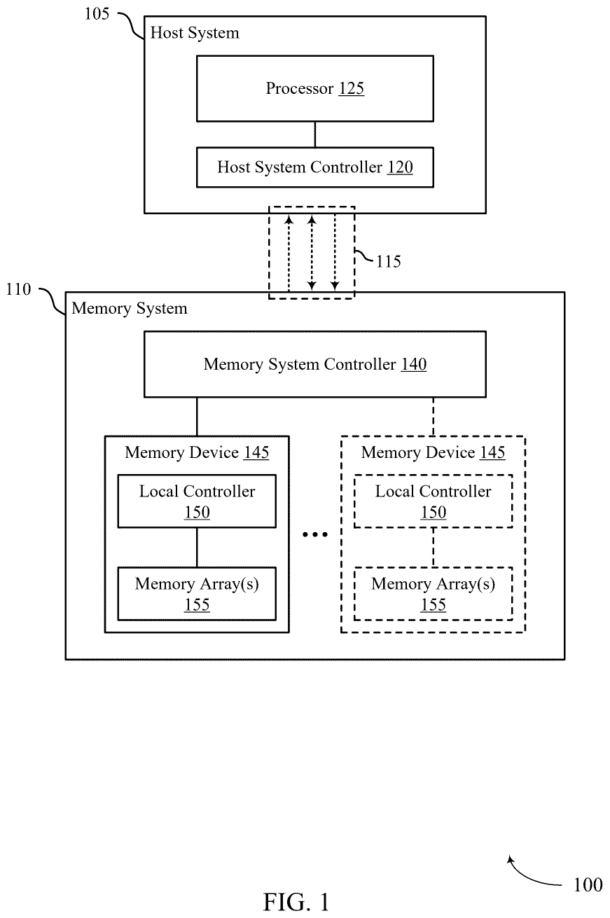

FIG. 1 shows an example of a system 100 that supports power and signal distribution in stacked semiconductor systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

In some examples of a system 100 or portion thereof, a stack of memory dies (e.g., memory chips, a memory stack, of a memory system 110, of an HBM or 3D stacked memory system) may be bonded on top of a logic component (e.g., a logic device, a logic die, a processing chip, of a memory system 110, including at least a portion of a memory system controller 140, of a host system 105, including a processor 125) in a heterogeneous stack (e.g., 3D stack including different die types). However, placing a relatively high-power logic component at or near the bottom of a heterogeneous stack may result in heat rejection challenges, because a thermal impedance of the memory dies may trap heat generated by the logic component. In some cases, thermal effects for heterogeneous stacks may be mitigated by placing a component with a relatively high thermal output (e.g., a relatively substantial heat source), such as a logic component, as an upper device (e.g., opposite a system substrate or installation surface) for closer integration with a heat sink. In some cases, placing a logic component over a stack of memory dies may be referred to as a Logic on Top (LoT) configuration. However, LoT configurations may be associated with challenges for providing power to different semiconductor components of a stack (e.g., providing power in accordance with different configurations to a logic component and one or more memory components), or for supporting serialized communications with the logic component (e.g., through or across a stack of memory components), or both.

In accordance with examples as disclosed herein, a semiconductor system (e.g., at least a portion of a system 100, in a LOT configuration) may be configured with a distribution component (e.g., a distribution die, an interposer, a logic I/O and PDN die) coupled with one or more memory components (e.g., one or more memory dies, of a memory stack, of a memory system 110) and a logic component (e.g., a logic die, a logic device, a processing chip, of a memory system 110, including at least a portion of a memory system controller 140, of a host system 105, including a processor 125). The distribution component may include power delivery circuitry (e.g., power distribution circuitry, a PDN) configured to provide separate power (e.g., in accordance with different voltages, different regulation schemes, different power conductors) to the one or more memory components and to the logic component. Additionally, or alternatively, the distribution component may include circuitry for data serialization and deserialization, which may communicate data signals with the logic component. Such techniques may support a relatively high power consumption for operations of a logic die and memory dies, while providing the logic die with a more-direct heat rejection path (e.g., opposite the stack of semiconductor components), which may support improved temperature uniformity, higher power density, higher processing density, improved processing speed, and overall improvements to user experience, among other benefits.

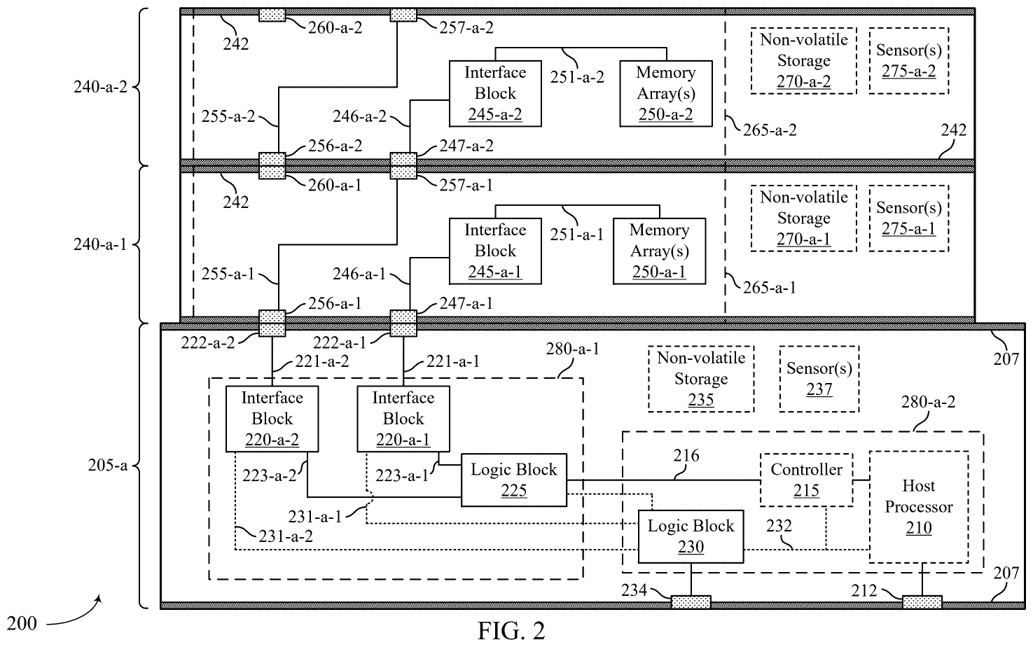

FIG. 2 shows an example of a system 200 (e.g., a semiconductor system, a system of coupled semiconductor dies, an HBM system, a 3D stacked memory system) that supports power and signal distribution in stacked semiconductor systems in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more TSVs).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In some implementations of a system 200, a stack of dies 240 may be bonded on top of a die 205. However, logic circuitry of a die 205 (e.g., of interface blocks 220, of logic block(s) 225, of a logic block 230, of controller(s) 215, of a host processor 210) may be associated with relatively high-power operations and accompanying heat generation, and locating a die 205 at or near the bottom of a stack (e.g., relatively close to a system substrate or assembly surface) may result in heat rejection challenges because a thermal impedance of the dies 240 may trap heat generated by the die 205. For example, heat generated by a die 205 in such an assembly may be transferred through dies 240 to a heat sink (e.g., on top of the dies 240), resulting in relatively high temperature gradient and peak temperature (e.g., at or near the die 205). In some cases, thermal effects for heterogeneous stacks may be mitigated by placing a die 205 as an upper device for closer integration with a heat sink, which may include placing a die 205 over a stack of dies 240 in accordance with a Logic on Top (LoT) configuration. However, LoT configurations may be associated with challenges for providing power to different semiconductor components of a stack (e.g., providing power in accordance with different configurations to die 205 and one or more dies 240), or for supporting serialized communications with the die 205 (e.g., with one or more interface blocks 220, with one or more controllers 215, via a host interface 216, with a host processor 210), or both.

In accordance with examples as disclosed herein, a semiconductor system (e.g., a system 200, in a LOT configuration) may include a distribution component (e.g., a distribution die, an interposer, a logic I/O and PDN die) coupled with one or more dies 240 and a die 205, where the distribution component may communicate power, signals (e.g., data signals), or both with the die(s) 240 and the die 205. The distribution component may include power delivery circuitry configured to provide separate power (e.g., in accordance with different voltages, different regulation schemes, different power conductors) to the dies 240 and the die 205. The distribution component may also include circuitry for data serialization and deserialization, which may communicate data signals with the die 205. In some cases, the distribution component may convey power, data signals, or both with the die 205 using conductive vias (e.g., TSVs) that pass through the die(s) 240 and bypass interface circuitry (e.g., interface blocks 245) of the die(s) 240. Additionally, or alternatively, the distribution component may include clock circuitry configured to provide clock signals for I/O functionality of the distribution component, for the die 205, for the interface circuitry (e.g., interface blocks 245), or any combination thereof. In some cases, the clock circuitry may receive one or more clock signals from another component (e.g., a substrate component, a host system, an external clock generator), or may generate one or more clock signals, or both. Such techniques may support a relatively high power consumption for operations of a die 205 and die(s) 240, while providing the die 205 with a more-direct heat rejection path (e.g., opposite the stack of semiconductor components), which may support improved temperature uniformity, higher power density, higher processing density, improved processing speed, and overall improvements to user experience, among other benefits.

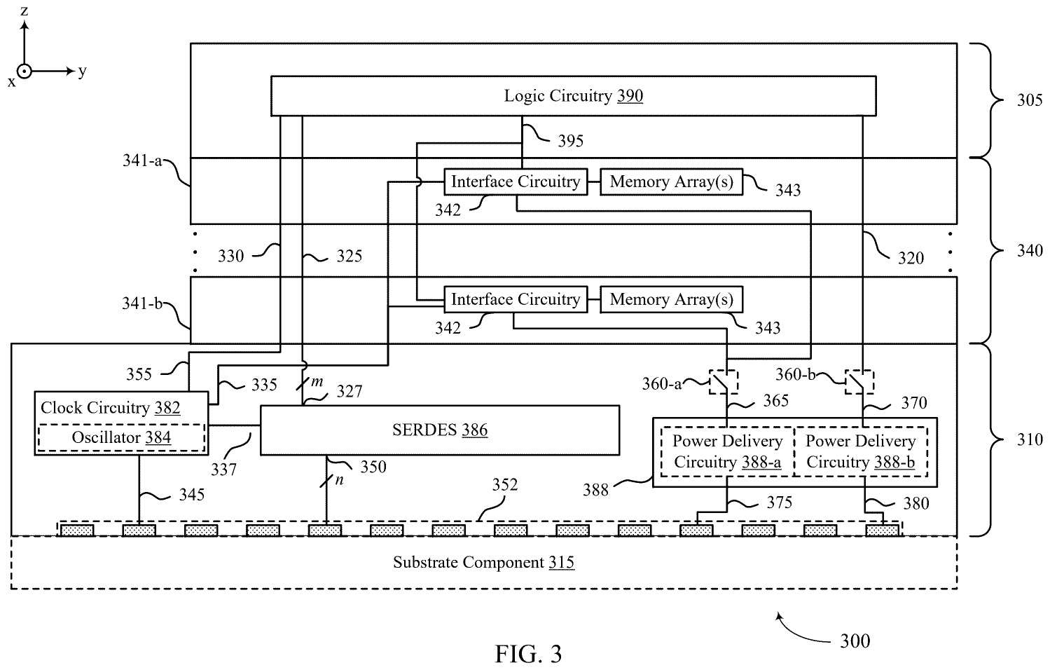

FIG. 3 shows an example of a system 300 (e.g., a semiconductor system) that supports power and signal distribution in stacked semiconductor systems in accordance with examples as disclosed herein. Aspects of the system 300 may be described with reference to an x-direction, a y-direction, and a z-direction of the illustrated coordinate system, where the z-direction may be illustrative of a direction (e.g., a vertical direction, a thickness direction, a stack direction) that is orthogonal to or otherwise relative to a surface in an xy-plane (e.g., a substrate plane, a coupling plane) of the system 300. Although FIG. 3 illustrates examples of relative dimensions and quantities of various features, aspects of a system 300 may be implemented with other relative dimensions or quantities of such features in accordance with examples as disclosed herein.

The system 300 may include a semiconductor component 305 (e.g., a logic die, a logic and compute die), which may be an example of aspects of a die 205. A semiconductor component 305 may include logic circuitry 390. In some examples, logic circuitry 390 may include one or more interface blocks 220, one or more logic blocks 225, a logic block 230, or a combination thereof (e.g., in an HBM implementation). Additionally, or alternatively, logic circuitry 390 may include one or more processing cores, and may be an example of aspects of a processor 125, a host processor 210, one or more controllers 215, or a combination thereof (e.g., in a 3D stacked memory implementation). For example, one or more processing cores of logic circuitry 390 may be associated with one or more GPUs, one or more CPUs, or other processing units. Although, in some examples, a semiconductor component 305 may be implemented as a single semiconductor die, in some other examples, a semiconductor component 305 may be implemented as multiple semiconductor dies (e.g., in a stacked arrangement, in an arrangement of chiplets, or both).

The system 300 may also include a set 340 of one or more semiconductor components 341 (e.g., semiconductor components 341-a and 341-b, semiconductor dies, memory dies, HBM dies, 3D stacked memory dies, a memory stack), each of which may be an example of aspects of a die 240. The set 340 (e.g., one or more of the semiconductor components 341) may include one or more memory arrays 343, each of which may be an example of a memory array 155 or a memory array 250, as well as interface circuitry 342 for accessing the memory array(s) 343, each of which may include respective interface blocks 245, among other circuitry. Each of the memory arrays 343 may be accessible by at least a portion of the logic circuitry 390 (e.g., via interface circuitry 342, via interface blocks 245, via interface blocks 220). For example, the logic circuitry 390 may be coupled with the interface circuitry 342 (e.g., one or more instances of interface circuitry 342) by one or more vias 395 (e.g., conductive vias, channels, wires, traces).

The semiconductor component 305 may be bonded with a first side (e.g., a top side, along the z-direction, a side in an xy-plane) of the set 340. In some implementations, a system 300 may support the semiconductor component 305 (e.g., logic circuitry 390) being situated on a face (e.g., on top) of the set 340, and receiving data signals, power input, or both, using one or more conductive vias (e.g., one or more vias 320, one or more vias 325, one or more vias 330) of a system 300. Although FIG. 3 illustrates a system 300 including two semiconductor components 341 in a stack, a system 300 in accordance with the described techniques may include a single semiconductor component 341, or any quantity of multiple semiconductor components 341 (e.g., two, four, eight, twelve, sixteen, or more), which may be bonded in a stack (e.g., a memory stack).

The system 300 may also include a semiconductor component 310 (e.g., a distribution die, a logic I/O and PDN die), which may be bonded with a second side (e.g., a bottom side) of the set 340. In various implementations, a semiconductor component 310 may include power delivery circuitry 388, SERDES 386 (e.g., one or more serialization/deserialization components), or clock circuitry 382, or a combination thereof.

In the example of FIG. 3, the system 300 (e.g., power delivery circuitry 388) includes power delivery circuitry 388-a and power delivery circuitry 388-b (e.g., multiple instances or portions of power delivery circuitry, multiple power delivery outputs). In some implementations, power delivery circuitry 388-a may have an output 365 that is coupled with the interface circuitry 342 of the semiconductor component(s) 341, and the power delivery circuitry 388-b may have an output 370 that is coupled with the logic circuitry 390 of the semiconductor component 305 by the one or more vias 320. Thus, the power delivery circuitry 388-a may output a first power (e.g., in accordance with a first voltage, in accordance with a first current) to the interface circuitry 342, and the power delivery circuitry 388-b may output a second power (e.g., in accordance with a second voltage, in accordance with a second current) to the logic circuitry 390. In some cases, the output 365 of the power delivery circuitry 388-a may be electrically isolated from the output 370 of the power delivery circuitry 388-b. For example, the output 365 (e.g., and a first power from the output 365) may be associated with (e.g., configured with, allocated to) a different voltage, a different current, or both, from the output 370 (e.g., and a second power from the output 370). In some cases, the voltage supplied to the logic circuitry 390 (e.g., by the output 370) may be greater than the voltage supplied to the interface circuitry 342 (e.g., by the output 365).

In some cases, one or more vias of the system 300 may extend through the semiconductor component(s) 341 and bypass interface circuitry 342, memory arrays 343, or both. For example, via(s) 320, via(s) 325, via(s) 330, or any combination thereof may be pass-through vias (e.g., TSVs) that pass through the semiconductor component(s) 341 and are isolated from (e.g., bypass) the interface circuitry 342, the memory arrays 343, or both. In some examples, one or more of the vias, channels, or conductive paths in the system 300 may be configured in a waterfall arrangement (e.g., waterfall TSVs), such as buses 255 of semiconductor component(s) 341 that may correspond to (e.g., be coupled with) vias 395. Additionally, or alternatively, an output 365 may distribute power to interface circuitry 342 of semiconductor component(s) 341 in such a waterfall arrangement. Additionally, or alternatively, such waterfall arranged conductive vias may connect components of the semiconductor component(s) 341 with components of a semiconductor component 305, a semiconductor component 310, or both.

A semiconductor component 310 may include one or more contacts 352 (e.g., conductive contacts, conductive material portions on a face of the semiconductor component 310, in an xy-plane). Contacts 352 may be located at a surface (e.g., a mounting surface, an assembly surface) of a semiconductor component 310 on a side that is different from (e.g., opposite from) the side of the semiconductor component 310 that is bonded with a set 340 of semiconductor component(s) 341.

In some cases, one or more of the contacts 352 may be configured to receive power, such as from a substrate component 315 (e.g., from one or more power conducting paths, not shown, of the substrate component 315), which may be a semiconductor substrate, an organic substrate (e.g., a printed circuit board substrate, a mother board, an assembly substrate). That is, one or more of the contacts 352 may be electrically coupled with one or more power conducting paths, for example, of the substrate component 315, and the one or more power conducting paths may transmit electrical power to the one or more of the contacts 352. For example, one or more of the contacts 352 may be coupled with an input 375 of the power delivery circuitry 388-a and may provide power to the power delivery circuitry 388-a, and one or more of the contacts 352 may be coupled with an input 380 of the power delivery circuitry 388-b and may provide power to the power delivery circuitry 388-b. Additionally, or alternatively, one or more of the contacts 352 may be coupled with the input 375 and the input 380, and may provide a common power input to the power delivery circuitry 388-a and 388-b. Thus, the power delivery circuitry 388 may receive first power through one or more of the contacts 352 and may distribute second power (e.g., output power) to portions of the system 300 based on the received first power.

In some cases, one or more of the contacts 352 may be configured to communicate control signaling to and from the system 300 (e.g., via a substrate component 315, to and from other systems or devices coupled with the substrate component 315). In some examples, such control signaling may be associated with the power delivery circuitry 388 (e.g., associated with the power delivery circuitry 388-a, the power delivery circuitry 388-b, or both). For example, control signaling may indicate a power level (e.g., a voltage, a current) associated with the output 365, the output 370, or both. Additionally, or alternatively, a semiconductor component 310 may include enabling circuitry 360 (e.g., enabling circuitry 360-a, enabling circuitry 360-b, switching circuitry, configuration circuitry) operable to enable or disable power delivery from the power delivery circuitry 388 (e.g., from the power delivery circuitry 388-a, from the power delivery circuitry 388-b, or both). In some cases, the control signaling may indicate whether the enabling circuitry 360 is to enable or disable power delivery from the power delivery circuitry 388. In some cases, the enabling circuitry 360 may include a switch, a microcontroller, or other circuitry.

In some implementations, a semiconductor component 310 may include clock circuitry 382, which may support generating or distributing one or more clock signals within the system 300. For example, clock circuitry 382 may be associated with one or more outputs 355 coupled with the logic circuitry 390, one or more outputs 335 coupled with interface circuitry 342, one or more outputs 337 coupled with a SERDES 386 of the semiconductor component 310, or any combination thereof. In some examples, clock circuitry 382 may output one or more clock signals to the logic circuitry 390, to the interface circuitry 342, to the SERDES 386, or any combination thereof. In some examples, such clock signals may be based on a clock signal generated by an oscillator 384 of the clock circuitry 382. That is, the clock circuitry 382 may generate (e.g., internally) at least one of the clock signals. Additionally, or alternatively, clock circuitry 382 may output one or more clock signals based on one or more received clock signals. For example, clock circuitry 382 may be associated with one or more inputs 345 (e.g., coupled with one or more contacts 352), and the clock circuitry 382 may be configured to receive one or more clock signals from the substrate component 315, and distribute a received clock signal or generate a new clock signal based on the received clock signal (e.g., with a different frequency, with a phase shift, with a time shift).

In some implementations, a semiconductor component 310 may include SERDES 386 (e.g., one or more instances of serialization/deserialization circuitry), which may support serializing data signals, deserializing data signals, or both (e.g., in accordance with different bus widths on different sides of SERDES 386). A SERDES 386 may have a port 327 coupled with the logic circuitry 390 (e.g., using vias 325) and a port 350 coupled with one or more of the contacts 352 (e.g., at a surface of the semiconductor component 310). In some cases, a port 327 may be coupled with logic circuitry 390 via m signal paths (e.g., having a bus width of m conductive paths), which may include one or more vias 325 that extend through semiconductor component(s) 341 and bypass the interface circuitry 342. A port 350 may be coupled with the one or more contacts 352 via n signal paths (e.g., having a bus width of n conductive paths), where n may be different from m. For example, the m signal paths (e.g., between the SERDES 386 and the logic circuitry 390) may be greater than the n signal paths (e.g., between the SERDES 386 and the contacts 352). In such examples, signals may be conveyed (e.g., transmitted, received) via port 327 in accordance with a lower frequency (e.g., lower switching frequency) than signals conveyed (e.g., received, transmitted) via port 350. In some examples, a SERDES 386 may perform deserializing, serializing, or both, based on (e.g., in accordance with) one or more clock signals (e.g., frequencies) received or generated by the clock circuitry 382 at the semiconductor component 310. In some cases, the difference between the first quantity n and the second quantity m may be due to the relatively high quantity of hybrid bond interconnections between the semiconductor components 305, 310, and 341 (e.g., based on the hybrid bonding), and manufacturing or interconnection techniques for relatively larger contacts 352 (e.g., relatively fewer contacts 352 per area of the substrate component 315, such as ball-outs or solder connections).

In some cases, a semiconductor component 310 may include multiple SERDES 386. For example, one or more SERDES 386 may be located on one or more edges (e.g., sides, in an xy-plane) of a semiconductor component 310, and may support a daisy chain structures for expanded capacity or connections to additional subsystems (e.g., NAND systems used for dynamic backup of DRAM contents, among others). In some cases, a SERDES 386 may be configured for communicating data signals (e.g., bidirectional information signaling) via the one or more contacts 352. For example, a host system (e.g., a host system 105) or other application system may transmit one or more data signals (e.g., read or write commands, application commands, I/O commands, other commands, data signals, information) to a system 300 (e.g., through one or more conductive paths of a substrate component 315 that are coupled with one or more of the contacts 352). A SERDES 386 may receive information signaling (e.g., one or more data signals) from another system through the contacts 352 (e.g., in accordance with n signal paths), deserialize (e.g., or serialize) the information signaling, and transmit the deserialized (e.g., or serialized) information signaling to the logic circuitry 390 through the one or more vias 325 (e.g., in accordance with m signal paths). In some cases, the information signaling may include data signaling, command signaling, or both. Deserializing the information signaling from n signal paths may provide a parallel output of the information signaling (e.g., parallel information signaling) via m signal paths, which may be greater than the n signal paths.

Additionally, or alternatively, logic circuitry 390 may communicate information outside a system 300 via a SERDES 386. For example, logic circuitry 390 may transmit information signaling destined for another device to a SERDES 386 through the one or more vias 325, and the SERDES 386 may receive and serialize (e.g., or deserialize) the information signaling, and transmit the serialized (e.g., or deserialized) information signaling to the other device through the contacts 352. Serializing the information signaling from m signal paths may provide a serial output of information signaling (e.g., serial information signaling) via the n signal paths based on the received information signaling.

In some examples, bonding of semiconductor components 305, 341, and/or 310 may include a fusion of conductive material of contacts of the respective components. In some examples, such a fusion of conductive materials may be accompanied by a fusion of dielectric materials (e.g., a dielectric material 207, a dielectric material 242) at the interfacing surfaces (e.g., in accordance with a hybrid bonding implementation). For example, a bonding of a semiconductor component 305 with a first side (e.g., top side) of a set 340, a bonding of the semiconductor component 310 with a second side (e.g., bottom side) of a set 340, or bonding among a set 340 of semiconductor components 341, may include a fusion of dielectric material portions, a fusion of conductive material portions (e.g., such as contacts 352), or both. For example, each of the semiconductor components 305, 310, and 341 may include one or more dielectric material portions and conductive material portions on a first (e.g., top) and second (e.g., bottom) side (e.g., as described with respect to the dielectric material 242 and the contacts of the dies 205-a and 240-a of FIG. 2). Such bonding may provide relatively small conductive interconnections between components of the system 300, which may be relatively large in quantity per area of a semiconductor component due to the relatively small size.

A manufacturing system may perform one or more operations to manufacture (e.g., form, assemble) a system 300. For example, a manufacturing system may bond a semiconductor component 310 with a first side (e.g., bottom) of a set 340 of one or more semiconductor component(s) 341 (e.g., using hybrid bonding). In some cases, bonding a semiconductor component 310 with a first side of a set 340 may include coupling an output 365 of power delivery circuitry 388-a with interface circuitry 342, coupling an output 370 of power delivery circuitry 388-b with logic circuitry 390 (e.g., through the one or more vias 320, if the semiconductor component 305 is already bonded with a second side of a set 340), or both.

Additionally, or alternatively, a manufacturing system may bond a semiconductor component 305 with a second side (e.g., top) of a set 340 of one or more semiconductor components 341. For example, bonding a semiconductor component 305 with a second side of a set 340 may include coupling logic circuitry 390 with interface circuitry 342 (e.g., via a waterfall arrangement, using one or more vias 395, via a bus 246, via a 221, via a bus 255). Additionally, or alternatively, bonding a semiconductor component 305 with a second side of a set 340 may include coupling an output 370 of power delivery circuitry 388-b of a semiconductor component 310 with logic circuitry 390 (e.g., through the one or more vias 320), coupling an output 355 of clock circuitry 382 with logic circuitry 390, or both.

Additionally, or alternatively, manufacturing a system 300 may include forming one or more conductive vias that extend through semiconductor component(s) 341 and bypass interface circuitry 342. For example, a manufacturing system may form vias 320, 325, 330, or any combination thereof, via one or more methods of formation (e.g., etching, cavity formation, filling with a conductive material).

Accordingly, a system 300 may include a semiconductor component 305 (e.g., a die, a set of dies) on a face of the system 300 (e.g., on top of a memory stack), and the semiconductor component 305 may receive data signaling, power, clock signaling, or any combination thereof from a semiconductor component 310. Such a configuration may improve thermal properties of the system 300 by increasing heat dissipation from the semiconductor component 305, and may allow for further flexibility for configuring the system 300. Such a configuration may also decouple a quantity of semiconductor component(s) 341 (e.g., a memory stack height) from increasing power loads used by the semiconductor component(s) 341, a semiconductor component 305, or both, because power delivery circuitry 388 may provide separate power supplies for semiconductor component(s) 341 and the semiconductor component 305.

Additionally, or alternatively, conductive vias (e.g., TSVs) of a system 300 may provide a high bandwidth connection between a semiconductor component 305 and external systems (e.g., via a semiconductor component 310). For example, compared to relatively large and/or sparse pitch contacts 352 (e.g., for solder connections), hybrid bonding (e.g., between semiconductor components) may provide a relatively dense pitch of interconnections (e.g., a small spacing between conductive vias), and a relatively dense pitch may reduce an impact of the vias on an overall size of the system 300, which may reduce power and area cost of I/O circuitry for the system 300. Thus, a semiconductor component 310 may provide efficient external I/O communication for the system 300 while improving system power distribution performance (e.g., for high capacity DRAM stacks).

In some cases, relatively small conductive vias may provide a relatively high bandwidth per pin set of connections between a semiconductor component 305 and a semiconductor component 310. Additionally, or alternatively, a relatively low parasitic loading of vias may allow relatively low-power and efficient I/O devices to utilize vias with reduced power and area overhead. The techniques described herein may also be scalable. For example, configurations for conductive vias in a system 300 (e.g., what each conductive via is used to communicate) may be configurable. Thus, the described techniques may allow a system 300 to be compatible with any size of various external I/O buses (e.g., standard I/O buses), which may allow various different systems 300 to leverage the high bandwidth capabilities of the system 300.

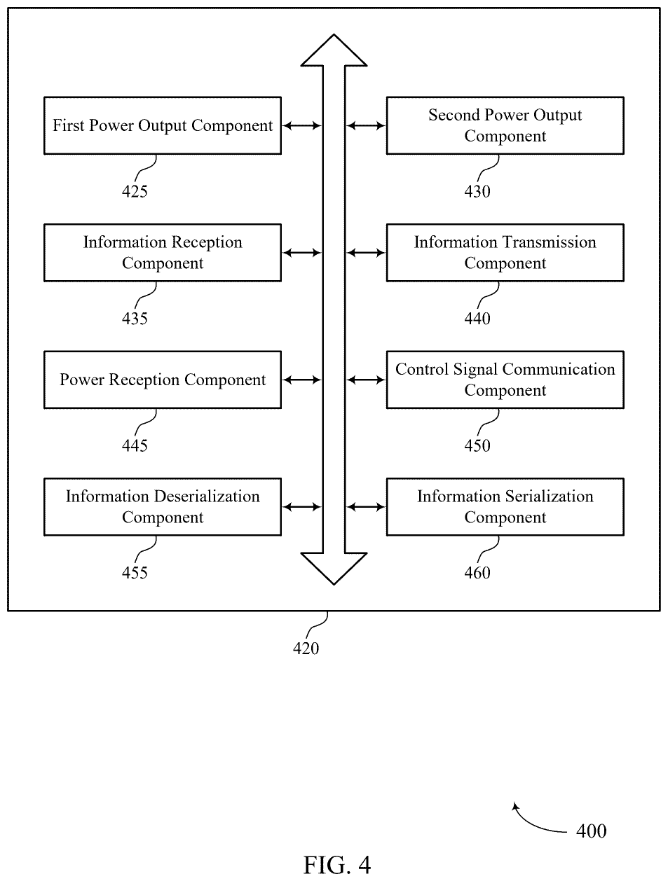

FIG. 4 shows a block diagram 400 of a semiconductor system 420 that supports power and signal distribution in stacked semiconductor systems in accordance with examples as disclosed herein. The semiconductor system 420 may be an example of aspects of a semiconductor system as described with reference to FIGS. 1 through 3. The semiconductor system 420, or various components thereof, may be an example of means for performing various aspects of power and signal distribution in stacked semiconductor systems as described herein. For example, the semiconductor system 420 may include a first power output component 425, a second power output component 430, an information reception component 435, an information transmission component 440, a power reception component 445, a control signal communication component 450, an information deserialization component 455, an information serialization component 460, or any combination thereof. Each of these components, or components of subcomponents thereof (e.g., one or more processors, one or more memories), may communicate, directly or indirectly, with one another (e.g., via one or more buses).

The semiconductor system 420 may include a bonded set (e.g., a stack) of semiconductor components, which may support operations (e.g., power distribution operations) in accordance with examples as disclosed herein. The first power output component 425 may be configured as or otherwise support a means for outputting first power from first power delivery circuitry of a third semiconductor component to interface circuitry of one or more first semiconductor components, the third semiconductor component bonded with a first side of the one or more first semiconductor components, and the interface circuitry for accessing one or more memory arrays of the one or more first semiconductor components. The second power output component 430 may be configured as or otherwise support a means for outputting second power from second power delivery circuitry of the third semiconductor component to logic circuitry of a second semiconductor component, the second semiconductor component bonded with a second side of the one or more first semiconductor components, and the logic circuitry coupled with the interface circuitry and operable to access the one or more memory arrays via the interface circuitry.

In some examples, the first power is output from a first output of the first power delivery circuitry, and the second power is output from a second output of the second power delivery circuitry that is electrically isolated from the first output. In some examples, the first power is associated with a different voltage, a different current, or both from the second power.

In some examples, the power reception component 445 may be configured as or otherwise support a means for receiving power through one or more conductive contacts at a surface of the third semiconductor component opposite the one or more first semiconductor components, where the first power and the second power are output based on the received power.

In some examples, the control signal communication component 450 may be configured as or otherwise support a means for communicating control signaling through one or more conductive contacts at a surface of the third semiconductor component opposite the one or more first semiconductor components the control signaling associated with the first power delivery circuitry, the second power delivery circuitry, or both.

Additionally, or alternatively, the semiconductor system 420 may support other operations (e.g., memory operations, serialization operations, deserialization operations) in accordance with examples as disclosed herein. The information reception component 435 may be configured as or otherwise support a means for receiving first information signaling at serialization/deserialization circuitry of a third semiconductor component that is bonded with a first side of one or more first semiconductor components, the one or more first semiconductor components including one or more memory arrays and interface circuitry for accessing the one or more memory arrays. The information transmission component 440 may be configured as or otherwise support a means for outputting second information signaling from the serialization/deserialization circuitry to logic circuitry of a second semiconductor component based on the first information signaling, the second semiconductor component bonded with a second side of the one or more first semiconductor components, and the logic circuitry coupled with the interface circuitry and operable to access the one or more memory arrays via the interface circuitry.

In some examples, the information deserialization component 455 may be configured as or otherwise support a means for deserializing the first information signaling from a first quantity of signal paths to provide a parallel output of the second information signaling via a second quantity of signal paths, the second quantity being greater than the first quantity.

In some examples, the information reception component 435 may be configured as or otherwise support a means for receiving third information signaling at the serialization/deserialization circuitry from the logic circuitry. In some examples, the information serialization component 460 may be configured as or otherwise support a means for serializing the third information signaling from the second quantity of signal paths to provide a serial output of fourth information signaling via the first quantity of signal paths based on the third information signaling.

In some examples, the deserializing is based on a clock signal received at the third semiconductor component.

In some examples, the first information signaling is received via a first quantity of signal paths of the third semiconductor component coupled with one or more conductive contacts at a surface of the third semiconductor component. In some examples, the second information signaling is output to the logic circuitry via a second quantity of signal paths through the one or more first semiconductor components.

In some examples, the first information signaling includes data signaling, command signaling, or a combination thereof.

In some examples, the described functionality of the semiconductor system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the semiconductor system 420, or various components thereof, may be implemented at least in part by instructions (e.g., stored in memory, non-transitory computer-readable medium) executable by such at least one processor.

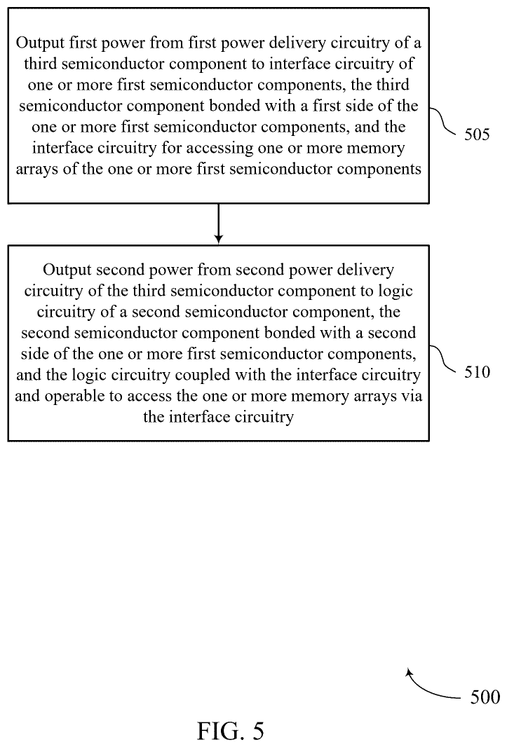

FIG. 5 shows a flowchart illustrating a method 500 that supports power and signal distribution in stacked semiconductor systems in accordance with examples as disclosed herein. The operations of method 500 may be implemented by a semiconductor system or its components as described herein. For example, the operations of method 500 may be performed by a semiconductor system as described with reference to FIGS. 1 through 4. In some examples, a semiconductor system may execute a set of instructions to control the functional elements of the device to perform the described functions. Additionally, or alternatively, the semiconductor system may perform aspects of the described functions using special-purpose hardware.

At 505, the method may include outputting first power from first power delivery circuitry (e.g., power delivery circuitry 388-a) of a third semiconductor component (e.g., a semiconductor component 310) to interface circuitry (e.g., interface circuitry 342) of one or more first semiconductor components (e.g., semiconductor component(s) 341), the third semiconductor component bonded with a first side of the one or more first semiconductor components, and the interface circuitry for accessing one or more memory arrays (e.g., memory array(s) 343) of the one or more first semiconductor components. In some examples, aspects of the operations of 505 may be performed by a first power output component 425 as described with reference to FIG. 4.

At 510, the method may include outputting second power from second power delivery circuitry (e.g., power delivery circuitry 388-b) of the third semiconductor component to logic circuitry (e.g., logic circuitry 390) of a second semiconductor component (e.g., semiconductor component 305), the second semiconductor component bonded with a second side of the one or more first semiconductor components, and the logic circuitry coupled with the interface circuitry and operable to access the one or more memory arrays via the interface circuitry. In some examples, aspects of the operations of 510 may be performed by a second power output component 430 as described with reference to FIG. 4.

In some examples, an apparatus (e.g., a semiconductor system) as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for outputting first power from first power delivery circuitry of a third semiconductor component to interface circuitry of one or more first semiconductor components, the third semiconductor component bonded with a first side of the one or more first semiconductor components, and the interface circuitry for accessing one or more memory arrays of the one or more first semiconductor components and outputting second power from second power delivery circuitry of the third semiconductor component to logic circuitry of a second semiconductor component, the second semiconductor component bonded with a second side of the one or more first semiconductor components, and the logic circuitry coupled with the interface circuitry and operable to access the one or more memory arrays via the interface circuitry.

Aspect 2: The method, apparatus, or non-transitory computer-readable medium of aspect 1, where the first power is output from a first output of the first power delivery circuitry and the second power is output from a second output of the second power delivery circuitry that is electrically isolated from the first output.

Aspect 3: The method, apparatus, or non-transitory computer-readable medium of aspect 2, where the first power is associated with a different voltage, a different current, or both from the second power.

Aspect 4: The method, apparatus, or non-transitory computer-readable medium of any of aspects 1 through 3, further including operations, features, circuitry, logic, means, or instructions, or any combination thereof for receiving power through one or more conductive contacts at a surface of the third semiconductor component opposite the one or more first semiconductor components, where the first power and the second power are output based on the received power.

Aspect 5: The method, apparatus, or non-transitory computer-readable medium of any of aspects 1 through 4, further including operations, features, circuitry, logic, means, or instructions, or any combination thereof for communicating control signaling through one or more conductive contacts at a surface of the third semiconductor component opposite the one or more first semiconductor components the control signaling associated with the first power delivery circuitry, the second power delivery circuitry, or both.

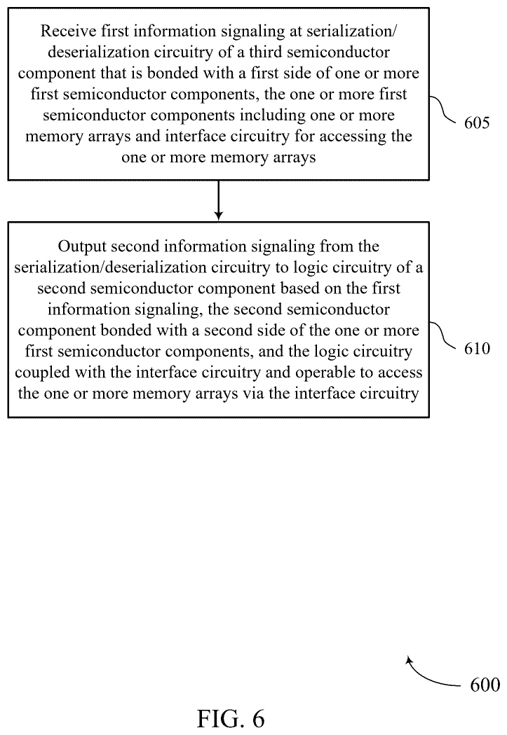

FIG. 6 shows a flowchart illustrating a method 600 that supports power and signal distribution in stacked semiconductor systems in accordance with examples as disclosed herein. The operations of method 600 may be implemented by a semiconductor system (e.g., a system 300) or its components as described herein. For example, the operations of method 600 may be performed by a semiconductor system as described with reference to FIGS. 1 through 4. In some examples, a semiconductor system may execute a set of instructions to control the functional elements of the device to perform the described functions. Additionally, or alternatively, the semiconductor system may perform aspects of the described functions using special-purpose hardware.

At 605, the method may include receiving first information signaling at serialization/deserialization circuitry (e.g., a SERDES 386) of a third semiconductor component (e.g., a semiconductor component 310) that is bonded with a first side of one or more first semiconductor components (e.g., semiconductor component(s) 341), the one or more first semiconductor components including one or more memory arrays (e.g., memory array(s) 343) and interface circuitry (e.g., interface circuitry 342) for accessing the one or more memory arrays. In some examples, aspects of the operations of 605 may be performed by an information reception component 435 as described with reference to FIG. 4.

At 610, the method may include outputting second information signaling from the serialization/deserialization circuitry to logic circuitry (e.g., logic circuitry 390) of a second semiconductor component (e.g., semiconductor component 305) based on the first information signaling, the second semiconductor component bonded with a second side of the one or more first semiconductor components, and the logic circuitry coupled with the interface circuitry and operable to access the one or more memory arrays via the interface circuitry. In some examples, aspects of the operations of 610 may be performed by an information transmission component 440 as described with reference to FIG. 4.

In some examples, an apparatus (e.g., a semiconductor system) as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 6: A method, apparatus, or non-transitory computer-readable medium including operations, features, circuitry, logic, means, or instructions, or any combination thereof for receiving first information signaling at serialization/deserialization circuitry of a third semiconductor component that is bonded with a first side of one or more first semiconductor components, the one or more first semiconductor components including one or more memory arrays and interface circuitry for accessing the one or more memory arrays and outputting second information signaling from the serialization/deserialization circuitry to logic circuitry of a second semiconductor component based on the first information signaling, the second semiconductor component bonded with a second side of the one or more first semiconductor components, and the logic circuitry coupled with the interface circuitry and operable to access the one or more memory arrays via the interface circuitry.

Aspect 7: The method, apparatus, or non-transitory computer-readable medium of aspect 6, further including operations, features, circuitry, logic, means, or instructions, or any combination thereof for deserializing the first information signaling from a first quantity of signal paths to provide a parallel output of the second information signaling via a second quantity of signal paths, the second quantity being greater than the first quantity.

Aspect 8: The method, apparatus, or non-transitory computer-readable medium of aspect 7, further including operations, features, circuitry, logic, means, or instructions, or any combination thereof for receiving third information signaling at the serialization/deserialization circuitry from the logic circuitry and serializing the third information signaling from the second quantity of signal paths to provide a serial output of fourth information signaling via the first quantity of signal paths based on the third information signaling.

Aspect 9: The method, apparatus, or non-transitory computer-readable medium of any of aspects 7 through 8, where the deserializing is based on a clock signal received at the third semiconductor component.

Aspect 10: The method, apparatus, or non-transitory computer-readable medium of any of aspects 6 through 9, where the first information signaling is received via a first quantity of signal paths of the third semiconductor component coupled with one or more conductive contacts at a surface of the third semiconductor component and the second information signaling is output to the logic circuitry via a second quantity of signal paths through the one or more first semiconductor components.

Aspect 11: The method, apparatus, or non-transitory computer-readable medium of any of aspects 6 through 10, where the first information signaling includes data signaling, command signaling, or a combination thereof.

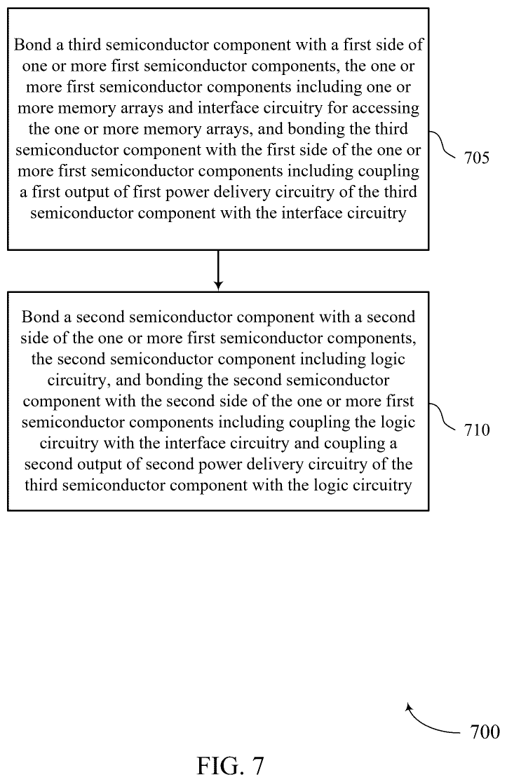

FIG. 7 shows a flowchart illustrating a method or methods 700 that supports power and signal distribution in stacked semiconductor systems in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, the one or more controllers may perform aspects of the described functions using special-purpose hardware.

At 705, the method may include bonding a third semiconductor component (e.g., semiconductor component 310) with a first side of one or more first semiconductor components (e.g., semiconductor component(s) 341), the one or more first semiconductor components including one or more memory arrays (e.g., memory array(s) 343) and interface circuitry (e.g., interface circuitry 342) for accessing the one or more memory arrays, and bonding the third semiconductor component with the first side of the one or more first semiconductor components including coupling a first output (e.g., output 365) of first power delivery circuitry (e.g., power delivery circuitry 388-a) of the third semiconductor component with the interface circuitry.

At 710, the method may include bonding a second semiconductor component (e.g., semiconductor component 305) with a second side of the one or more first semiconductor components, the second semiconductor component including logic circuitry (e.g., logic circuitry 390), and bonding the second semiconductor component with the second side of the one or more first semiconductor components including coupling the logic circuitry with the interface circuitry and coupling a second output (e.g., output 370) of second power delivery circuitry (e.g., power delivery circuitry 388-b) of the third semiconductor component with the logic circuitry.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 12: A method or apparatus including operations, features, circuitry, logic, means, or instructions, or any combination thereof for bonding a third semiconductor component with a first side of one or more first semiconductor components, the one or more first semiconductor components including one or more memory arrays and interface circuitry for accessing the one or more memory arrays, and bonding the third semiconductor component with the first side of the one or more first semiconductor components including coupling a first output of first power delivery circuitry of the third semiconductor component with the interface circuitry and bonding a second semiconductor component with a second side of the one or more first semiconductor components, the second semiconductor component including logic circuitry, and bonding the second semiconductor component with the second side of the one or more first semiconductor components including coupling the logic circuitry with the interface circuitry and coupling a second output of second power delivery circuitry of the third semiconductor component with the logic circuitry.

Aspect 13: The method or apparatus of aspect 12, where the first output of the first power delivery circuitry is electrically isolated from the second output of the second power delivery circuitry.

Aspect 14: The method or apparatus of any of aspects 12 through 13, further including operations, features, circuitry, logic, means, or instructions, or any combination thereof for forming one or more conductive vias extending through the one or more first semiconductor components and bypassing the interface circuitry, the second output of the second power delivery circuitry coupled with the logic circuitry through the one or more conductive vias.

Aspect 15: The method or apparatus of any of aspects 12 through 14, where the bonding of the second semiconductor component with the first side of the one or more first semiconductor components, the bonding of the third semiconductor component with the second side of the one or more first semiconductor components, or both include a fusion of dielectric material portions and a fusion of conductive material portions.

It should be noted that the aspects described herein describe possible implementations, and that the operations and the steps may be rearranged or otherwise modified and that other implementations are possible. Further, portions from two or more of the methods may be combined.

An apparatus (e.g., a semiconductor system) is described. The following provides an overview of aspects of the apparatus as described herein:

Aspect 16: A semiconductor system (e.g., a system 300), including: one or more first semiconductor components (e.g., semiconductor component(s) 341) including one or more memory arrays (e.g., memory array(s) 343) and interface circuitry (e.g., interface circuitry 342) for accessing the one or more memory arrays, a second semiconductor component (e.g., a semiconductor component 305) bonded with a first side of the one or more first semiconductor components, the second semiconductor component including logic circuitry (e.g., logic circuitry 390) that is coupled with the interface circuitry; and a third semiconductor component (e.g., a semiconductor component 310) bonded with a second side of the one or more first semiconductor components, the third semiconductor component including first power delivery circuitry (e.g., power delivery circuitry 388-a) having a first output (e.g., an output 365) that is coupled with the interface circuitry and including second power delivery circuitry (e.g., power delivery circuitry 388-b) having a second output (e.g., an output 370) that is coupled with the logic circuitry.

Aspect 17: The semiconductor system of aspect 16, where the first output of the first power delivery circuitry is electrically isolated from the second output of the second power delivery circuitry.

Aspect 18: The semiconductor system of aspect 17, where the first output of the first power delivery circuitry is associated with a different voltage, a different current, or both compared with the second output of the second power delivery circuitry.

Aspect 19: The semiconductor system of any of aspects 16 through 18, further including: one or more conductive vias extending through the one or more first semiconductor components and bypassing the interface circuitry, the second output of the second power delivery circuitry coupled with the logic circuitry through the one or more conductive vias.

Aspect 20: The semiconductor system of any of aspects 16 through 19, where the third semiconductor component includes one or more conductive contacts at a surface of the third semiconductor component opposite the one or more first semiconductor components, the one or more conductive contacts configured to receive power and being coupled with a first input of the first power delivery circuitry and with a second input of the second power delivery circuitry.

Aspect 21: The semiconductor system of any of aspects 16 through 20, where the third semiconductor component includes one or more conductive contacts at a surface of the third semiconductor component opposite the one or more first semiconductor components and configured to communicate control signaling associated with the first power delivery circuitry, the second power delivery circuitry, or both.

Aspect 22: The semiconductor system of any of aspects 16 through 21, where the third semiconductor component includes circuitry operable to enable or disable power delivery from the first output of the first power delivery circuitry, from the second output of the second power delivery circuitry, or both.

Aspect 23: The semiconductor system of any of aspects 16 through 22, where the third semiconductor component includes clock circuitry having one or more first outputs coupled with the logic circuitry, one or more second outputs coupled with interface circuitry, or both, the clock circuitry configured to output one or more clock signals based on an oscillator of the clock circuitry, based on one or more received clock signals, or a combination thereof.

Aspect 24: The semiconductor system of any of aspects 16 through 23, where the bonding of the second semiconductor component with the first side of the one or more first semiconductor components, the bonding of the third semiconductor component with the second side of the one or more first semiconductor components, or both include a fusion of dielectric material portions and a fusion of conductive material portions.

An apparatus (e.g., a semiconductor system) is described. The following provides an overview of aspects of the apparatus as described herein:

Aspect 25: A semiconductor system (e.g., a system 300), including: one or more first semiconductor components (e.g., semiconductor component(s) 341) including one or more memory arrays (e.g., memory array(s) 343) and interface circuitry (e.g., interface circuitry 342) for accessing the one or more memory arrays; a second semiconductor component (e.g., a semiconductor component 305) bonded with a first side of the one or more first semiconductor components, the second semiconductor component including a logic circuitry (e.g., logic circuitry 390) that is coupled with the interface circuitry; and a third semiconductor component (e.g., a semiconductor component 310) bonded with a second side of the one or more first semiconductor components, the third semiconductor component including serialization/deserialization circuitry (e.g., SERDES 385) having a first port (e.g., a port 327) that is coupled with the logic circuitry and a second port (e.g., a port 350) that is coupled with one or more conductive contacts (e.g., contact(s) 352) at a surface of the third semiconductor component.

Aspect 26: The semiconductor system of aspect 25, where: the first port of the serialization/deserialization circuitry is coupled with the logic circuitry via a first quantity of signal paths through the one or more first semiconductor components; and the second port of the serialization/deserialization circuitry is coupled with the one or more conductive contacts via a second quantity of signal paths of the third semiconductor component different from the first quantity.

Aspect 27: The semiconductor system of aspect 26, where the first quantity of signal paths include one or more conductive vias extending through the one or more first semiconductor components and bypassing the interface circuitry.

Aspect 28: The semiconductor system of any of aspects 25 through 27, where the serialization/deserialization circuitry is configured for communicating bidirectional information signaling via the one or more conductive contacts.

Aspect 29: The semiconductor system of any of aspects 25 through 28, where the third semiconductor component includes clock circuitry having one or more first outputs coupled with the logic circuitry, one or more second outputs coupled with interface circuitry, one or more third outputs coupled with the serialization/deserialization circuitry, or a combination thereof, the clock circuitry configured to output one or more clock signals based on an oscillator of the clock circuitry, based on one or more received clock signals, or a combination thereof.

Aspect 30: The semiconductor system of any of aspects 25 through 29, where the bonding of the second semiconductor component with the first side of the one or more first semiconductor components, the bonding of the third semiconductor component with the second side of the one or more first semiconductor components, or both include a fusion of dielectric material portions and a fusion of conductive material portions.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor system, comprising:
one or more first semiconductor components comprising one or more memory arrays and interface circuitry for accessing the one or more memory arrays,
a second semiconductor component bonded with a first side of the one or more first semiconductor components, the second semiconductor component comprising logic circuitry that is coupled with the interface circuitry; and
a third semiconductor component bonded with a second side of the one or more first semiconductor components, the third semiconductor component comprising first power delivery circuitry having a first output that is coupled with the interface circuitry and comprising second power delivery circuitry having a second output that is coupled with the logic circuitry.

2. The semiconductor system of claim 1, wherein the first output of the first power delivery circuitry is electrically isolated from the second output of the second power delivery circuitry.

3. The semiconductor system of claim 2, wherein the first output of the first power delivery circuitry is associated with a different voltage, a different current, or both compared with the second output of the second power delivery circuitry.

4. The semiconductor system of claim 1, further comprising:
one or more conductive vias extending through the one or more first semiconductor components and bypassing the interface circuitry, the second output of the second power delivery circuitry coupled with the logic circuitry through the one or more conductive vias.

5. The semiconductor system of claim 1, wherein the third semiconductor component comprises one or more conductive contacts at a surface of the third semiconductor component opposite the one or more first semiconductor components, the one or more conductive contacts configured to receive power and being coupled with a first input of the first power delivery circuitry and with a second input of the second power delivery circuitry.

6. The semiconductor system of claim 1, wherein the third semiconductor component comprises one or more conductive contacts at a surface of the third semiconductor component opposite the one or more first semiconductor components and configured to communicate control signaling associated with the first power delivery circuitry, the second power delivery circuitry, or both.

7. The semiconductor system of claim 1, wherein the third semiconductor component comprises circuitry operable to enable or disable power delivery from the first output of the first power delivery circuitry, from the second output of the second power delivery circuitry, or both.

8. The semiconductor system of claim 1, wherein the third semiconductor component comprises clock circuitry having one or more first outputs coupled with the logic circuitry, one or more second outputs coupled with interface circuitry, or both, the clock circuitry configured to output one or more clock signals based on an oscillator of the clock circuitry, based on one or more received clock signals, or a combination thereof.

9. The semiconductor system of claim 1, wherein the bonding of the second semiconductor component with the first side of the one or more first semiconductor components, the bonding of the third semiconductor component with the second side of the one or more first semiconductor components, or both include a fusion of dielectric material portions and a fusion of conductive material portions.

10. A method for operating a semiconductor system, comprising:
outputting first power from first power delivery circuitry of a third semiconductor component to interface circuitry of one or more first semiconductor components, the third semiconductor component bonded with a first side of the one or more first semiconductor components, and the interface circuitry for accessing one or more memory arrays of the one or more first semiconductor components; and
outputting second power from second power delivery circuitry of the third semiconductor component to logic circuitry of a second semiconductor component, the second semiconductor component bonded with a second side of the one or more first semiconductor components, and the logic circuitry coupled with the interface circuitry and operable to access the one or more memory arrays via the interface circuitry.

11. The method of claim 10, wherein:
the first power is output from a first output of the first power delivery circuitry; and
the second power is output from a second output of the second power delivery circuitry that is electrically isolated from the first output.

12. The method of claim 11, wherein the first power is associated with a different voltage, a different current, or both from the second power.

13. The method of claim 10, further comprising:
receiving power through one or more conductive contacts at a surface of the third semiconductor component opposite the one or more first semiconductor components, wherein the first power and the second power are output based on the received power.

14. The method of claim 10, further comprising:
communicating control signaling through one or more conductive contacts at a surface of the third semiconductor component opposite the one or more first semiconductor components the control signaling associated with the first power delivery circuitry, the second power delivery circuitry, or both.

15. A method of forming a semiconductor apparatus, comprising:
bonding a third semiconductor component with a first side of one or more first semiconductor components, the one or more first semiconductor components comprising one or more memory arrays and interface circuitry for accessing the one or more memory arrays, and bonding the third semiconductor component with the first side of the one or more first semiconductor components comprising coupling a first output of first power delivery circuitry of the third semiconductor component with the interface circuitry; and
bonding a second semiconductor component with a second side of the one or more first semiconductor components, the second semiconductor component comprising logic circuitry, and bonding the second semiconductor component with the second side of the one or more first semiconductor components comprising coupling the logic circuitry with the interface circuitry and coupling a second output of second power delivery circuitry of the third semiconductor component with the logic circuitry.

16. The method of claim 15, wherein the first output of the first power delivery circuitry is electrically isolated from the second output of the second power delivery circuitry.

17. The method of claim 15, further comprising:
forming one or more conductive vias extending through the one or more first semiconductor components and bypassing the interface circuitry, the second output of the second power delivery circuitry coupled with the logic circuitry through the one or more conductive vias.

18. The method of claim 15, wherein the bonding of the second semiconductor component with the first side of the one or more first semiconductor components, the bonding of the third semiconductor component with the second side of the one or more first semiconductor components, or both comprise a fusion of dielectric material portions and a fusion of conductive material portions.

19. A semiconductor system, comprising:
one or more first semiconductor components comprising one or more memory arrays and interface circuitry for accessing the one or more memory arrays;
a second semiconductor component bonded with a first side of the one or more first semiconductor components, the second semiconductor component comprising a logic circuitry that is coupled with the interface circuitry; and
a third semiconductor component bonded with a second side of the one or more first semiconductor components, the third semiconductor component comprising serialization/deserialization circuitry having a first port that is coupled with the logic circuitry and a second port that is coupled with one or more conductive contacts at a surface of the third semiconductor component.

20. The semiconductor system of claim 19, wherein:
the first port of the serialization/deserialization circuitry is coupled with the logic circuitry via a first quantity of signal paths through the one or more first semiconductor components; and
the second port of the serialization/deserialization circuitry is coupled with the one or more conductive contacts via a second quantity of signal paths of the third semiconductor component different from the first quantity.

21. The semiconductor system of claim 20, wherein the first quantity of signal paths comprise one or more conductive vias extending through the one or more first semiconductor components and bypassing the interface circuitry.

22. The semiconductor system of claim 19, wherein the serialization/deserialization circuitry is configured for communicating bidirectional information signaling via the one or more conductive contacts.

23. The semiconductor system of claim 19, wherein the third semiconductor component comprises clock circuitry having one or more first outputs coupled with the logic circuitry, one or more second outputs coupled with interface circuitry, one or more third outputs coupled with the serialization/deserialization circuitry, or a combination thereof, the clock circuitry configured to output one or more clock signals based on an oscillator of the clock circuitry, based on one or more received clock signals, or a combination thereof.

24. The semiconductor system of claim 19, wherein the bonding of the second semiconductor component with the first side of the one or more first semiconductor components, the bonding of the third semiconductor component with the second side of the one or more first semiconductor components, or both comprise a fusion of dielectric material portions and a fusion of conductive material portions.

25. A method for memory operations at a memory apparatus, comprising:
receiving first information signaling at serialization/deserialization circuitry of a third semiconductor component that is bonded with a first side of one or more first semiconductor components, the one or more first semiconductor components comprising one or more memory arrays and interface circuitry for accessing the one or more memory arrays; and
outputting second information signaling from the serialization/deserialization circuitry to logic circuitry of a second semiconductor component based on the first information signaling, the second semiconductor component bonded with a second side of the one or more first semiconductor components, and the logic circuitry coupled with the interface circuitry and operable to access the one or more memory arrays via the interface circuitry.

26. The method of claim 25, further comprising:
deserializing the first information signaling from a first quantity of signal paths to provide a parallel output of the second information signaling via a second quantity of signal paths, the second quantity being greater than the first quantity.

27. The method of claim 26, further comprising:
receiving third information signaling at the serialization/deserialization circuitry from the logic circuitry; and
serializing the third information signaling from the second quantity of signal paths to provide a serial output of fourth information signaling via the first quantity of signal paths based on the third information signaling.

28. The method of claim 26, wherein the deserializing is based on a clock signal received at the third semiconductor component.

29. The method of claim 25, wherein:
the first information signaling is received via a first quantity of signal paths of the third semiconductor component coupled with one or more conductive contacts at a surface of the third semiconductor component; and
the second information signaling is output to the logic circuitry via a second quantity of signal paths through the one or more first semiconductor components.

30. The method of claim 25, wherein the first information signaling comprises data signaling, command signaling, or a combination thereof.
